(19) United States
(12) Patent Application Publication
(10) Pub. No.: US 2008/0251114 A1
(43) Pub. Date: Oct. 16, 2008

(54) Method For Packing Solar Battery Elements and Package For Solar Battery Elements

(75) Inventors: Kumeharu Tanaka, Shiga (JP); Kousei Shimizu, Shiga (JP); Ryuichi Sakamoto, Shiga (JP)

Correspondence Address: HOGAN & HARTSON L.L.P., 1999 AVENUE OF THE STARS, SUITE 1400, LOS ANGELES, CA, 90067, US

(73) Assignee: Kyocera Corporation, Kyoto-shi, Kyoto (JP)

(21) Appl. No.: 11/909,975

(22) PCT Filed: Mar. 28, 2006
(86) PCT No.: PCT/JP2006/306360

§ 371 Date: Sep. 27, 2007

(30) Foreign Application Priority Data
Mar. 29, 2005 (JP) 2005-093592

(51) Int. Cl. H01L 31/042

(52) U.S. Cl. 136/251

(57) ABSTRACT

An object of the invention is to provide a method for packing solar battery elements where cracking or chipping does not occur during the packing work and transportation, and the solar battery elements can be easily packed. In addition, in order to achieve the above described object, the method includes: a first packing step of covering a plurality of layered solar battery elements (3) with a heat-shrinkable film (4); a first heating step of heating this heat-shrinkable film (4) so that the solar battery elements 3 are held as an assembly (5); and a second packing step of inserting the assembly (5) into an opening (2) of a container (1) having the opening (2) for holding this assembly (5).

### TECHNICAL FIELD

The present invention relates to a method for packing solar battery elements, and in particular, to a packing method and a package which allow solar battery elements to be transported safely by reducing the damage to the solar battery elements.

### BACKGROUND TECHNOLOGY

Solar batteries convert incident light energy to electrical energy. Solar batteries are mainly classified as crystal based solar batteries, amorphous based solar batteries, compound based solar batteries and the like, depending on the type of material used. From among these, most of those circulated in markets at present are crystal based silicon solar batteries, and solar battery elements fabricated from a single crystal or a polycrystal silicon substrate are provided in a thin substrate having a thickness of approximately 200 μm to 300 μm or less, and therefore, feeble against impact and vibration, and thus, cracking and chipping easily occur when solar battery elements are transported.

FIG. 22 shows conventional containers for carrying solar battery elements. FIG. 22(a) is a perspective diagram showing a buffering body 101 used according to a conventional method for packing solar battery elements 103. FIG. 22(b) is a perspective diagram showing a package for solar battery elements. 101 indicates buffering bodies, 102 indicates holding trenches, 103 indicates solar battery elements and 108 indicates fixtures.

In accordance with a conventional packing method for safely transporting solar battery elements 103 without damaging them when the solar battery elements 103 are shipped, as shown in FIG. 22(a), buffering bodies 101, of which the cross section is in approximately L shape and where a plurality of holding trenches 102 are provided on the inside along the L shape in order to hold solar battery elements 103 parallel at intervals in the direction of the thickness, for example, are prepared, as shown in FIG. 22(b), a plurality of solar battery elements 103 are placed parallel to each other at predetermined intervals, and the corner portions of the respective substrates are inserted into the holding trenches 102 of the above described buffering bodies 101, respectively, so that the four sides of the solar battery elements 103 are fit into the trenches, and the outside is fixed with fixtures 108, such as rubber straps or tape, and thus, the buffering bodies 101 and the solar battery elements 103 are held. Furthermore, the entirety is packaged with a heat-shrinkable film (not shown) and a heat-shrinking process is carried out, and thus, foreign matters, such as dust, can be prevented from being mixed in while the heat-shrinkable film is thermally shrunk so that the entirety of the buffering body is pressed, and the solar battery elements 103 are held so as not to be removed from the holding trenches 102 of the buffering bodies 101 (for example, Japanese Unexamined Patent Publication 2003-292087). The package in which the plurality of solar battery elements 103 are held by the buffering bodies 101 is packed into a receptacle, such as a container or a cardboard box, where the inside is surrounded with a buffering material such as polypropylene foam or sponge, and transported to the shipping destination.

### DISCLOSURE OF THE INVENTION

In the conventional structure, however, it is necessary to set the solar battery elements 103 in the trenches of the buffering bodies 101 one by one, and therefore, the packing work is extremely troublesome. In addition, when the buffering bodies 101 in approximately L shape are attached to the solar battery elements 103, the buffering bodies 101 are attached to the corner portions of the solar battery elements 103, and therefore, chipping and cracking frequently occur in corner portions of the solar battery elements 103 due to mistakes in the handling by the worker.

In addition, in the portions where the solar battery elements 103 and the buffering bodies 101 make contact, the force of binding by the fixture 108 and the heat shrinkable film is great. Therefore, the area of contact between the buffering bodies 101 and the solar battery elements 103 is small in such a manner that a large amount of stress is applied to the outer periphery portion of the solar battery elements 103, and thus, there is a possibility that cracking may occur in the outer periphery portion of the solar battery elements 103.

Furthermore, in the case where the width of the holding trenches 102 provided in the buffering bodies 101 is made too small in order to firmly hold the solar battery elements 103 and the thickness of the solar battery elements 103 is, for example, 300 μm or less, the solar battery elements 103 are easily bent and broken when the solar battery elements 103 are inserted, and therefore, the working hours become long because prudent work becomes necessary in order to avoid damage. As a result, it becomes necessary to increase the precision in the width of the holding trenches 102, and consequently, problems arise such that the cost for processing the holding trenches 102 becomes high and the cost for transportation greatly increases, particularly when the buffering bodies 101 are disposed of at the shipping destination without being reused.

The present invention is provided in view of these problems with the prior art, and an object thereof is to provide a method for packing solar battery elements and a package where cracking and chipping can be prevented from occurring during the packing work and transportation, and the solar battery elements can be easily packed.

In order to achieve the above described object, the method for packing solar battery elements according to the first aspect includes: a first packing step of covering a plurality of layered solar battery elements with a heat-shrinkable film; a first heating step of heating the above described heat-shrinkable film so that the above described solar battery elements are held as an assembly; and a second packing step of inserting the above described assembly into an opening of a container containing the opening for holding the above described assembly.

In this manner, the method includes: a first packing step of covering a plurality of layered solar battery elements with a heat-shrinkable film; a first heating step of heating the above described heat-shrinkable film so that the above described solar battery elements are held as an assembly; and a second packing step of inserting the above described assembly into an opening of a container having the opening for holding the above described assembly, and therefore, the solar battery elements covered with the heat-shrinkable film are not exposed to air, and thus, effects, such as oxidation of the electrodes, can be suppressed.

In addition, since the solar battery elements are layered as an assembly, the solar battery elements are held by the entirety of the surfaces of the assembly within the container instead of by the end portions of the solar battery elements according to the prior art, and therefore, the area of contact between the container and the assembly increases so that stress applied to the solar battery elements through impact can be dispersed. Furthermore, cracking and chipping in end portions of the solar battery elements can be prevented from occurring through vibrations at the time of transportation and handling and through impact when being dropped because the solar battery elements are held by the entirety of the surfaces of the assembly.

The method for packing solar battery elements according to the second embodiment is the method for packing solar battery elements according to the first embodiment, wherein a cut is provided in the inner surface of the above described opening in the direction of the layering of the above described solar battery elements.

The method for packing solar battery elements according to the third embodiment is the method for packing solar battery elements according to the first embodiment, wherein a recess is provided in the inner surface of the above described opening in the direction of the layering of the above described solar battery elements.

The method for packing solar battery elements according to the fourth embodiment is the method for packing solar battery elements according to the first embodiment, wherein the above described container has a plurality of openings in the direction of the layering of the above described solar battery elements and is provided with a penetrating portion for connecting adjacent inner surfaces of the plurality of openings.

The method for packing solar battery elements according to the fifth embodiment is the method for packing solar battery elements according to any of the first to fourth embodiments, wherein a trench is provided in the bottom corner of the above described opening.

The method for packing solar battery elements according to the sixth embodiment is the method for packing solar battery elements according to any of the first to fifth embodiments, wherein a lid for covering the above described opening is provided, and the above described lid is fit to the above described container.

The method for packing solar battery elements according to the seventh embodiment is the method for packing solar battery elements according to the sixth embodiment, wherein the above described lid is made of the same container as the above described container.

The method for packing solar battery elements according to the eighth embodiment is the method for packing solar battery elements according to the sixth or seventh embodiment, which includes: a third packing step of fitting the above described lid to the above described container and covering the two with a heat-shrinkable film; and a second heating step of heating the heat-shrinkable film so that the above described lid and the above described container are integrated.

The package for solar battery elements according to the ninth embodiment is a package for solar battery elements comprising: an assembly of solar battery elements in which a plurality of layered solar battery elements are held to each other; and a container containing an opening, where the above described assembly of solar battery elements is placed inside the opening, wherein each of the above described solar battery elements has an electrode at least on its nonlight-receiving surface, and the above described assembly of solar battery elements has layers where the above described electrodes face the same direction.

As described above, a plurality of layered solar battery elements are held to each other in the assembly of solar battery elements so that a sufficient strength can be secured in the assembly of solar battery elements, and thus, cracking and chipping can be prevented from occurring during packing work and transportation, and the solar battery elements can be easily packed.

In particular, each of the solar battery elements has an electrode at least on its nonlight-receiving surface, and the above described assembly of solar battery elements has layers where the above described electrodes face the same direction, and therefore, the direction of warping of the solar battery elements becomes uniform in a certain direction, and thus, a sufficient strength can further be secured.

The package for solar battery elements according to the tenth embodiment is a package for solar battery elements comprising: an assembly of solar battery elements in which a plurality of layered solar battery elements are held to each other; and a container containing an opening, where the above described assembly of solar battery elements is placed inside the opening, wherein a side of the layers of the above described assembly of solar battery elements is located on the bottom surface side of the above described opening.

As described above, a plurality of layered solar battery elements are held to each other in the assembly of solar battery elements so that a sufficient strength can be secured in the assembly of solar battery elements, and thus, cracking and chipping can be prevented from occurring during packing work and transportation, and the solar battery elements can be easily packed.

In addition, a side of the layers of the assembly of solar battery elements is located on the bottom surface side of the above described opening, and thus, the weight of the solar battery elements can be dispersed instead of being collected to a certain solar battery element at the time of packing.

The package for solar battery elements according to the eleventh embodiment is the package for solar battery elements according to the ninth or tenth embodiment, wherein the above described assembly of solar battery elements is held in an airtight state with a heat-shrinkable film which covers the assembly.

The package for solar battery elements according to the twelfth embodiment is the package for solar battery elements according to any of the ninth to eleventh embodiments, wherein the above described container includes a cut in an inner wall which forms the above described opening.

The package for solar battery elements according to the thirteenth embodiment is the package for solar battery elements according to any of the ninth to eleventh embodiments, wherein the above described container includes a recess in an inner wall which forms the above described opening.

The package for solar battery elements according to the fourteenth embodiment is the package for solar battery elements according to any of the ninth to eleventh embodiments, wherein the above described opening is approximately in rectangular parallelepiped form and includes a trench in its bottom corner.

The package for solar battery elements according to the fifteenth embodiment is the package for solar battery elements according to any of the ninth to fourteenth embodiments, wherein the above described container includes a plurality of openings.

The package for solar battery elements according to the sixteenth embodiment is the package for solar battery elements according to the fifteenth embodiment, wherein the above described plurality of openings are provided so as to be aligned in the direction in which the solar battery elements which form assemblies of solar battery elements placed inside the openings, which are the same as the above described assembly, are layered.

The package for solar battery elements according to the seventeenth embodiment is the package for solar battery elements according to the sixteenth embodiment, wherein the above described container includes a cut in the inner wall which forms the above described opening, wherein the above described cut is provided so as to connect adjacent openings.

The package for solar battery elements according to the eighteenth embodiment is the package for solar battery elements according to the sixteenth embodiment, wherein the above described container includes a recess in the inner wall which forms the above described openings, wherein the above described recess is provided so as to connect adjacent openings.

The package for solar battery elements according to the nineteenth embodiment is the package for solar battery elements according to any of the ninth to eighteenth embodiments, wherein an outer surface of the above described container has projection and concave.

The package for solar battery elements according to the twentieth embodiment is the package for solar battery elements according to nineteenth embodiment, wherein an outer surface of the above described container corresponding to the location of the above described opening is in concave form.

The package for solar battery elements according to the twenty-first embodiment is the package for solar battery elements according to any of the ninth to twentieth embodiments, further having a lid for covering at least a portion of the above described opening in a state where the above described assembly of solar battery elements is placed inside the above described opening.

The package for solar battery elements according to the twenty-second embodiment is the package for solar battery elements according to the twenty-first embodiment, wherein the above described lid is fit to the above described container.

The package for solar battery elements according to the twenty-third embodiment is the package for solar battery elements according to the twenty-first or twenty-second embodiment, wherein the above described lid has the same form as the above described container.

The package for solar battery elements according to the twenty-fourth embodiment is made by sealing the package for solar battery elements according to any of the ninth to twenty-third embodiments airtight with a heat-shrinkable film.

The method for packing solar battery elements according to the twenty-fifth embodiment includes: the step of layering solar battery elements including an electrode at least on a nonlight-receiving surface in such a manner that the above described electrodes face the same direction; an assembly forming step of forming an assembly of solar battery elements by securing a plurality of layered solar battery elements with a packing member; and an assembly inserting step of placing the above described assembly of solar battery elements inside an opening of a container including the opening.

The method for packing solar battery elements according to the twenty-sixth embodiment includes: an assembly forming step of forming an assembly of solar battery elements by securing a plurality of layered solar battery elements with a packing member; and an assembly inserting step of inserting the above described assembly of solar battery elements into an opening of a container including the opening so that a side of the layers is located on the bottom surface side of the above described opening.

The method for packing solar battery elements according to the twenty-seventh embodiment is the method for packing solar battery elements according to the twenty-fifth or twenty-sixth embodiment, wherein an assembly of solar battery elements is formed by covering the outside of a plurality of layered solar battery elements with a heat-shrinkable film and heating the heat-shrinkable film in the above described assembly forming step.

Objects, features, aspects and advantages of this invention will be clarified more from the following detailed description and the attached drawings.

### BRIEF DESCRIPTION OF DRAWINGS

FIG. 1(a), FIG. 1(b) and FIG. 1(c) are diagrams illustrating the first packing step and the first heating step in the method for packing semiconductor battery elements according to the present invention;

FIG. 2(a), FIG. 2(b) and FIG. 2(c) are diagrams illustrating the first packing step and the first heating step in another method for packing semiconductor battery elements according to the present invention;

FIG. 3 is a diagram illustrating one embodiment where openings are provided according to a method for packing solar battery elements of the present invention;

FIG. 4 is a schematic diagram illustrating another embodiment where notches are provided in the openings according to a method for packing solar battery elements of the present invention;

FIG. 5 is a schematic diagram illustrating another embodiment where recesses are provided in the openings according to a method for packing solar battery elements of the present invention;

FIG. 6 is a schematic diagram illustrating another embodiment where openings are connected according to a method for packing solar battery elements of the present invention;

FIG. 7 is a diagram showing an enlarged bottom corner A in an opening of FIG. 3 in another embodiment according to a method for packing solar battery elements of the present invention;

FIG. 8 is a schematic diagram showing another embodiment according to a method for packing solar battery elements of the present invention;

FIG. 9(a) and FIG. 9(b) are schematic diagrams showing another embodiment according to a method for packing solar battery elements of the present invention;

FIG. 10 is a schematic diagram showing another embodiment according to a method for packing solar battery elements of the present invention;

FIG. 11 is a schematic diagram showing another embodiment according to a method for packing solar battery elements of the present invention;

FIG. 12 is a diagram showing an fitting portion 14 provided in a joining portion between a container 1 and a lid 6;

FIG. 13 is a cross sectional diagram showing the structure of a general solar battery element;

FIG. 14 is a diagram showing an example of an electrode form in a general solar battery element, where FIG. 14(a) shows the light receiving surface side (front surface) and FIG. 14(b) shows the surface side which does not receive light (rear surface);

FIG. 15 is a diagram showing an example of an electrode form in a solar battery element which is used in the method for packing solar battery elements of the present invention, where FIG. 15(a) shows the light receiving surface side (front surface) and FIG. 15(b) shows the surface side which does not receive light (rear surface);

FIG. 16 is a schematic diagram showing another embodiment according to the method for packing solar battery elements of the present invention, wherein FIG. 16(a) is a perspective diagram, FIG. 16(b) is a front cross sectional diagram and FIG. 16(c) is a top plan diagram;

FIG. 17 is a schematic diagram showing another embodiment according to the method for packing solar battery elements of the present invention;

FIG. 18 is a schematic diagram showing another embodiment according to the method for packing solar battery elements of the present invention;

FIG. 19 is a schematic diagram showing another embodiment according to the package for solar battery elements of the present invention;

FIG. 20 is a schematic diagram showing another embodiment according to the method for packing solar battery elements of the present invention;

FIG. 21 is a schematic diagram showing another embodiment according to the method for packing solar battery elements of the present invention; and

FIG. 22(a) is a perspective diagram showing a buffering body in a method for packing solar battery elements according to the prior art, and FIG. 22(b) is a perspective diagram showing a package for elements.

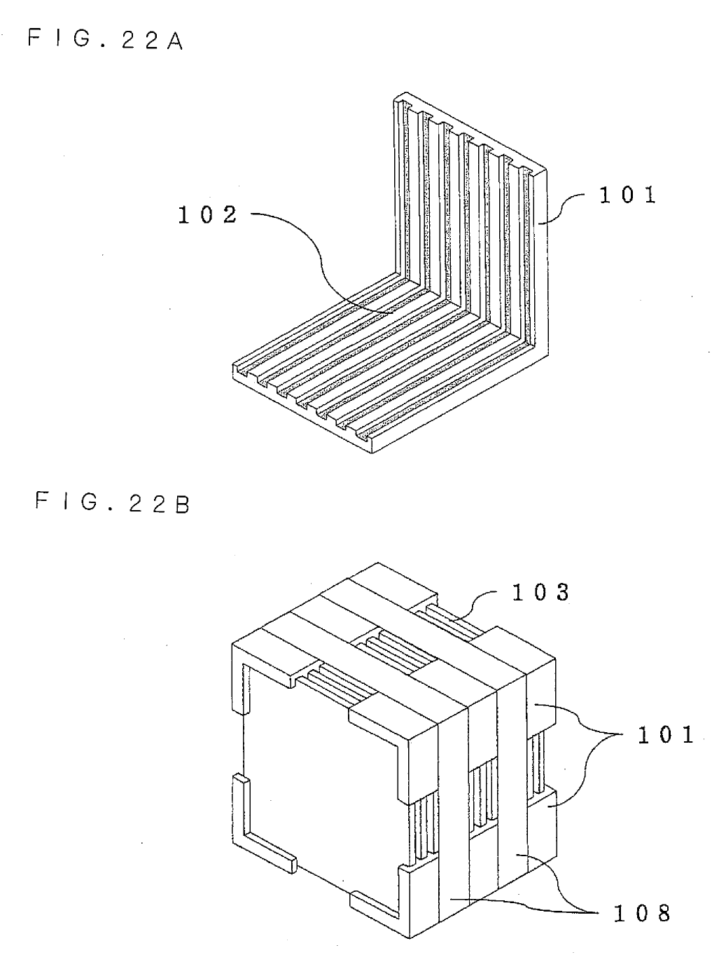

### BEST MODE FOR CARRYING OUT THE INVENTION

In the following, the method for packing solar battery elements according to the present invention is described. In the present document, an opening 2 indicates the entirety of a recess formed in a container 1.

First, solar battery elements, which are articles to be packed according to the present invention, are described.

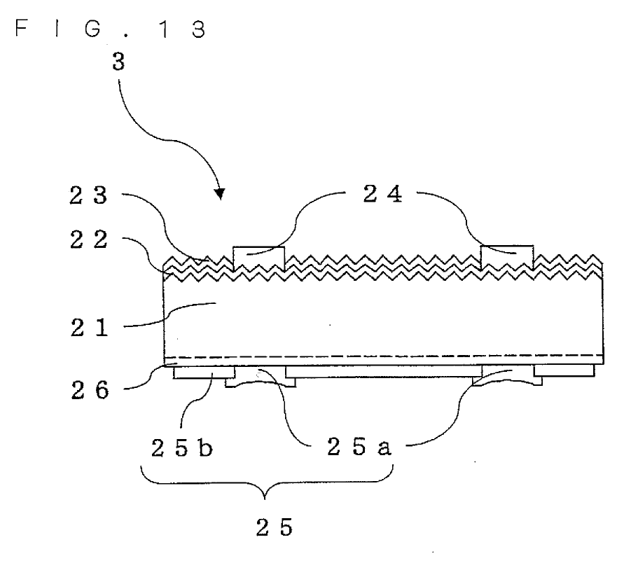

FIG. 13 is a schematic diagram showing the structure of a solar battery element in the present invention. 21 indicates a semiconductor substrate, 22 indicates a diffusion layer, 23 indicates a reflection preventing film, 24 indicates a front surface electrode, 25 indicates a rear surface electrode, 25a indicates rear surface busbar electrodes, 25b indicates a rear surface electricity collecting electrode and 26 indicates a rear surface electrical field region.

A semiconductor substrate 21 of a p type semiconductor made of single crystal silicon or polycrystal silicon having a thickness of approximately 0.2 mm to 0.5 mm and dimensions of approximately 100 mm×100 mm to 150 mm×150 mm, for example, is prepared. Then, phosphorous or the like, which is an n type impurity, is diffused in the semiconductor substrate 21 so that a diffusion layer 22 of the n type is provided, and a pn junction is formed vis-à-vis the p type semiconductor substrate 21.

A reflection preventing film 23 is formed of, for example, a silicon nitride film on the light receiving surface side of the solar battery element in order to prevent solar light from being reflected.

Then, a silver paste is applied to the light receiving surface side (front surface) of the semiconductor substrate 21 and an aluminum and a silver paste are applied to the surface side which does not receive light (rear surface), and the substrate is sintered so that the front surface electrode 24 and the rear surface electrode 25 are formed.

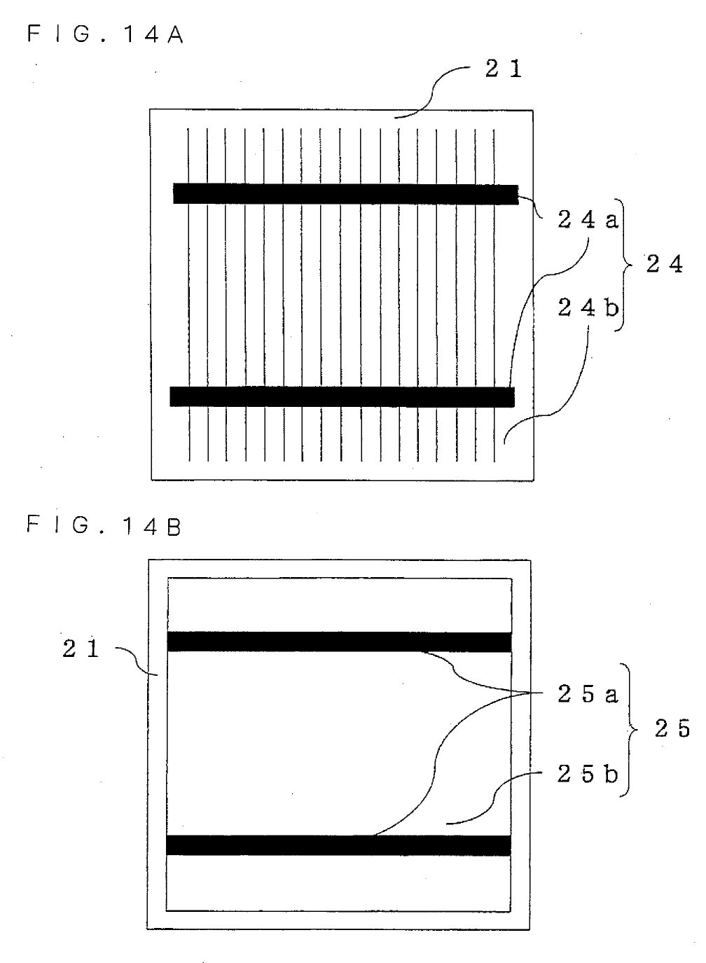

FIG. 14 shows an example of an electrode structure of a solar battery element according to the present invention. FIG. 14(a) shows the light receiving surface side (front surface) and FIG. 14(b) shows the surface side which does not receive light (rear surface).

As shown in FIG. 14(a), the surface electrodes 24 of which the main component is silver are formed of front surface busbar electrodes 24a for extracting the output from the front surface, and front surface finger electrodes 24b for collecting electricity, which are provided so as to be perpendicular to the front surface busbar electrodes. In addition, as shown in FIG. 14(b), the rear surface electrode 25 is formed of rear surface busbar electrodes 25a of which the main component is silver for extracting the output from the rear surface, and rear surface electricity collecting electrodes 25b of which the main component is aluminum.

When the rear surface electricity collecting electrodes 25b are formed by applying an aluminum paste in accordance with a screen printing method and burning it, aluminum, which works as a p type impurity element for the semiconductor substrate 21 of silicon, diffuses in the semiconductor substrate 21, and thus, a rear surface electrical field region 26 having a high concentration is formed.

In addition, the rear surface electrode 25 may be formed in grid form of a plurality of narrow finger electrodes 24b and wide busbar electrodes 24a, which are perpendicular to the finger electrodes 24b, as the front surface electrode 24 shown in FIG. 14(a).

After that, if necessary, the front surface electrode 24 and the rear surface electrode 25 (electrodes of which the main component is silver) are coated with solder (not shown). The resistance loss of the electrodes can be decreased by coating the electrodes with solder, and thus, the electrodes can be used for the connection with inner leads (not shown) for extracting the output to the outside. For this coating with solder, a dipping method, a wave soldering system or the like can be adopted.

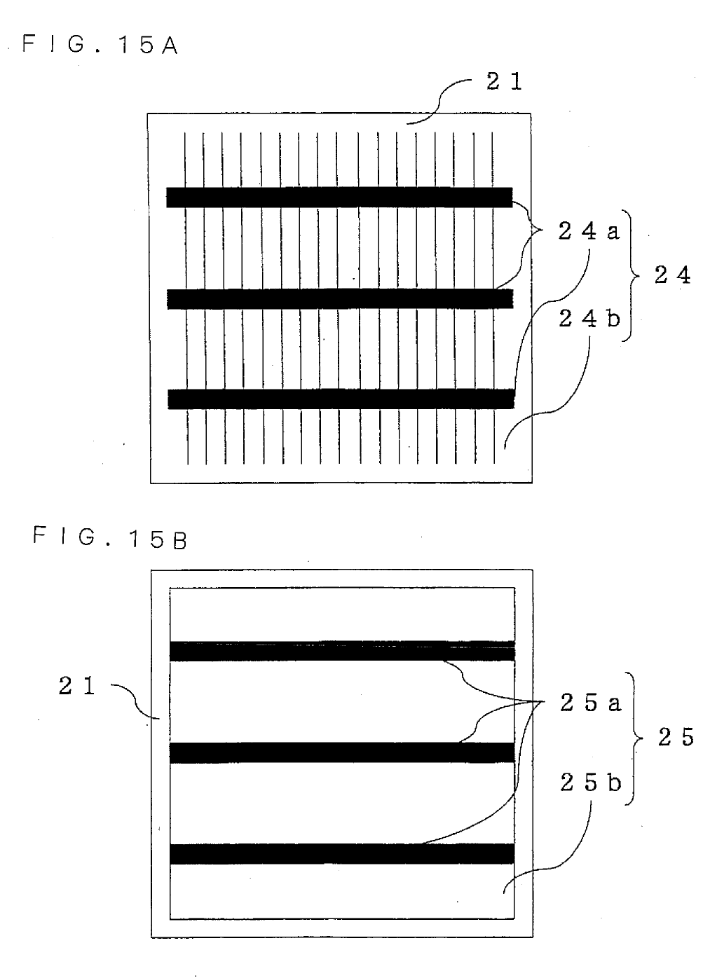

Here, FIG. 15 shows another type of solar battery element 3 according to the present invention, and in this manner, the electrodes may be formed of three front surface busbar electrodes 24a and three rear surface busbar electrodes 25a.

As described above, there is a high possibility of the manufactured solar battery elements 3 warping in the vicinity of the center portion of the substrate 21 due to the difference in the coefficient of thermal expansion between the substrate 21 and the front surface electrode 24 or the rear surface electrode 25, and the warped state is maintained after being cooled. Therefore, these solar battery elements 3 are packed within a container in accordance with the below described method for packing solar battery elements according to the present invention, and thus, a method for packing solar battery elements 3 can be provided in order to prevent such problems as cracking and chipping.

In the following, the method for packing solar battery elements according to the present invention is described.

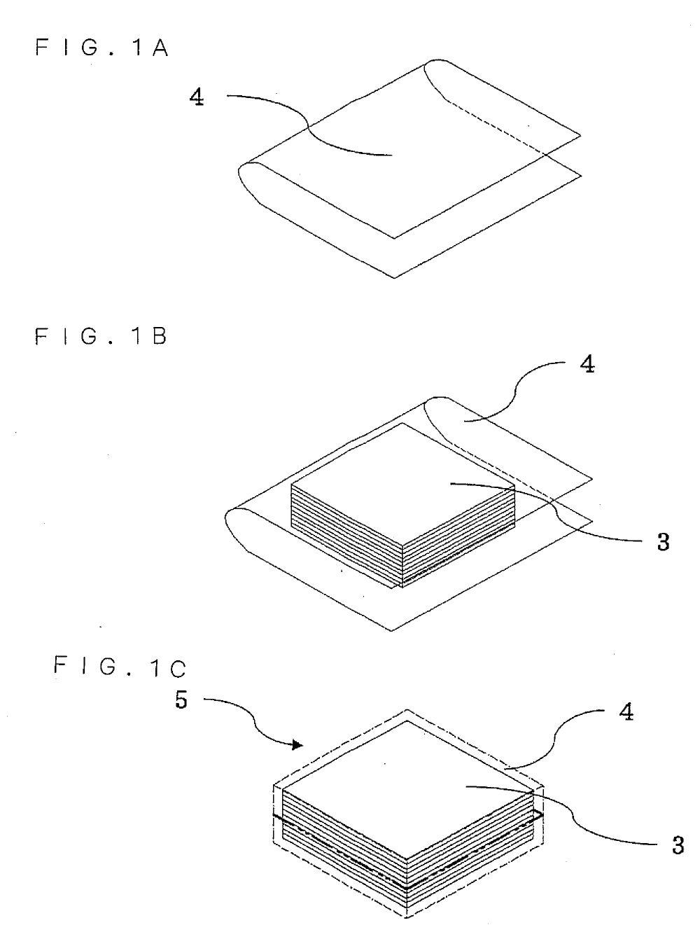

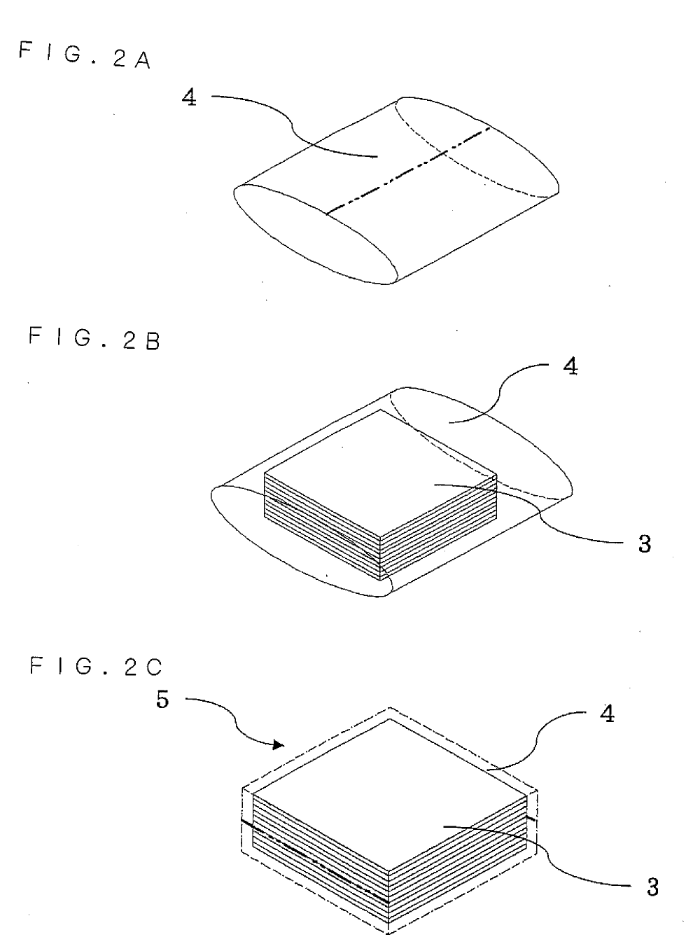

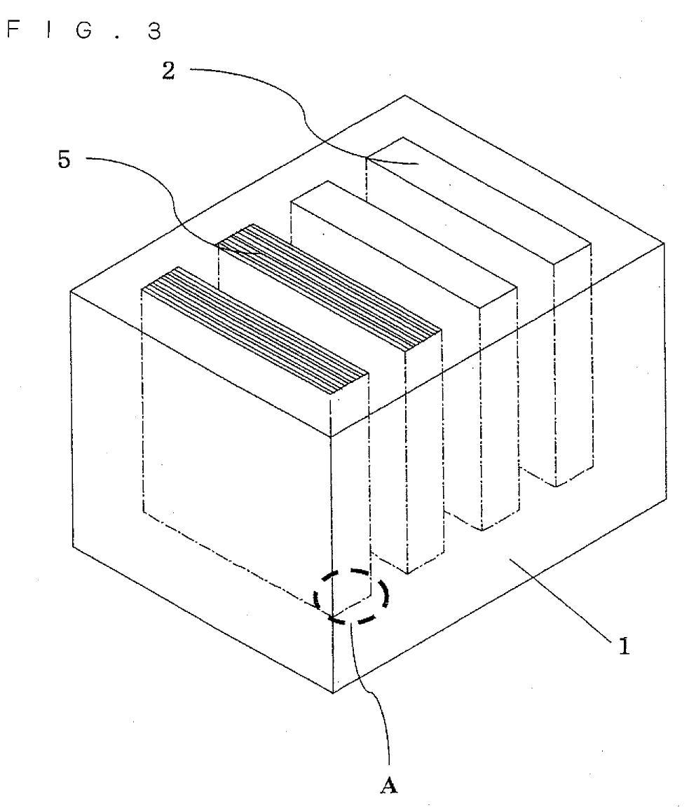

FIG. 1 and FIG. 2 are diagrams showing a first packing step and a first heating step of the present invention, and FIG. 3 is a schematic diagram showing a second packing step of the present invention. 1 indicates a container (containment body), 2 indicates openings, 3 indicates solar battery elements, 4 indicates a heat-shrinkable film, 5 indicates an assembly and A surrounded by a thick dotted line indicates the bottom corner of an opening.

As shown in FIG. 1(a) and FIG. 2, in the first packing step of layering a plurality of solar battery elements 3 and coating the layered body with a heat-shrinkable film 4, a plurality of solar battery elements 3 can be bundled, and the heat-shrinkable film 4 shrinks in the first heating step, which is a post process, so that the solar battery elements 3 can be held as the assembly, which is shielded from the outside air, and where the solar battery elements 3 do not move relative to each other. In addition, the method for packing solar battery elements 3 according to the present invention includes a second packing step of inserting an assembly 5 where a plurality of solar battery elements 3 are layered and held with the heat-shrinkable film 4 into a container 1 having openings 2 as shown in FIG. 3. Inserting an assembly 5 into an opening 2 according to the present invention means, in other words, putting an assembly into an opening.

Next, the first packing step, the first heating step and the second packing step according to the present invention are described in detail.

(1) First Packing Step and First Heating Step

First, there is an L type sealing system as one means for the first packing step of packing a plurality of layered solar battery elements 3 with a heat-shrinkable film 4. As shown in FIG. 1(a), one heat-shrinkable film 4 is folded in half along the longitudinal direction with an opening having a cross section in approximately U form. Next, as shown in FIG. 1(b), layered solar battery elements 3 are introduced into the opening of the heat-shrinkable film 4 having a cross section in approximately U form. Finally, in the first heating step, the opening of the heat-shrinkable film 4 in three directions is fused and cut with an L type heat sealer as shown in FIG. 1(c), and after that, the heat-shrinkable film 4 is heated by a heating apparatus, which is referred to as a shrink tunnel, at a temperature of approximately 90° C. to 140° C. so that the film is thermally shrunk, and thus, the heat-shrinkable film 4 adheres to the outer surface of the solar battery elements 3, and the solar battery elements 3 are held. As a result, an assembly 5 is formed. Here, the above described heat-shrinkable film 4 is a packing member for securing a plurality of layered solar battery elements 3 in a packed state.

In addition, there is an I type sealing system as another method where, as shown in FIG. 2(a), one heat-shrinkable film 4 is folded in half along the longitudinal direction and the two end portions are fused so that a cylinder is formed. Next, as shown in FIG. 2(b), layered solar battery elements 3 are introduced into the opening of the heat-shrinkable film 4 in cylindrical form. Finally, as shown in FIG. 2(c), the openings at both ends of the heat-shrinkable film 4 are fused and cut with a heat sealer in linear form, and after that, the solar battery elements 3 are made to pass through a shrink tunnel so that the heat-shrinkable film 4 adheres to the outer surface of the solar battery elements 3, and the solar battery elements 3 are held. As a result, an assembly 5 is formed. Thus, an assembly 5 where the heat-shrinkable film 4 covering the solar battery elements 3 holds the respective solar battery elements 3 in an airtight state can be gained. In this manner, the assembly 5 is in an airtight state, and therefore, the electrodes 24 and 25 of each solar battery element 3 can be effectively prevented from being oxidized by the air. This assembly 5 is formed in approximately rectangular parallelepiped form having the front surface and the rear surface, which are formed of the main surfaces of the solar battery elements 3, and four layered sides, which are a collection of the respective sides of the solar battery elements 3 in layer form.

It is possible to carry out such shrink packing using a general shrink packing apparatus, and as the heat-shrinkable film 4, films having a thickness of approximately 10 μm to 50 μm of polyvinyl chloride, polystyrene, polyester, polyethylene, polyolefin and the like can be used.

Here, in the present assembly 5, the respective solar battery elements 3 are layered so that the rear surface electrode 25 on the surface side which does not receive light (rear surface) faces the same direction. That is to say, the direction of warping is determined by the rear surface electrode 25 formed on the surface side which does not receive light (rear surface) in each solar battery element 3. In the case where the direction of warping of each solar battery element 3 is inconsistent, excessive stress tends to be applied between the solar battery elements 3 of which the warping is inconsistent, and thus, the solar battery elements 3 are easily damaged. Therefore, the solar battery elements 3 are layered so that the rear surface electrodes 25 face the same direction as described above, and thus, the direction of warping of the solar battery elements 3 can be made uniform so that the assembly 5 is excellent in its strength as a whole.

(2) Second Packing Step

In addition, in the second packing step as shown in FIG. 3, the container 1 has openings 2 into which an assembly 5 can be inserted and held, and assemblies 5 are inserted into these openings 2 in such a manner that the direction of layers of the solar battery elements 3 is toward sides. These openings 2 have an approximately rectangular parallelepiped form corresponding to the outer shape of the above described assemblies 5. Concretely, the openings 2 are formed in approximately parallelepiped form having inner surfaces corresponding to the front surface (one main surface) and the rear surface (the other main surface) and three layer side surfaces of the assembly 5. In addition, the assemblies 5 can be contained in the openings 2 in a state where one layer side surface of each assembly 5 is located on the bottom surface side of the opening 2. A foam resin material, such as polystyrene foam, polyethylene foam or polypropylene foam, is used for this container 1, and the container 1 can be formed by carrying out an appropriate cutting process or a slicing process on a foam resin material having a form for multiple purposes, such as a plate form or a block form, so that the form of the container 1 can be gained, or integrally forming foam beads in accordance with a bead forming method where beads are foamed and formed within a mold having a predetermined form. In addition, it is desirable to provide a plurality of openings 2 so that a great number of assemblies 5 can be contained at the same time.

As described above, the method includes the first packing step, the first heating step and the second packing step, and thus, the work becomes very easy, and chipping and cracking in the corner portions of the solar battery elements 3 due to mistakes in handling by the worker can be prevented from occurring. In addition, the solar battery elements 3 are covered with a heat-shrinkable film 4 so as not to be exposed to the air, and thus, the electrodes of the solar battery elements 3 can be prevented from being oxidized or receiving such effects as described above. In addition, when the solar battery elements 3 are layered, stress applied to the solar battery elements is dispersed to the overlapped solar battery elements 3, and furthermore, when a thermally shrinking process is carried out on the solar battery elements packed with a heat-shrinkable film 4, the solar battery elements adhere to each other and are held within the heat-shrinkable film so that the assembly 5 can be regarded as one substrate having a thickness that is equal to the total thickness of the overlapped solar battery elements, and the assembly 5 has a strength corresponding to the thickness of the packed element body, and therefore, cracking of the solar battery elements can be prevented.

Furthermore, assemblies 5 are held within openings 2 without fail using the elasticity of the container 1, and therefore, the precision in processing as high as in the prior art is not necessary for the formation of the container 1, and as a result, the cost for processing can be reduced, and in particular, when the container 1 is disposed of at the shipment destination without being reused, the cost for transportation can be greatly reduced. In order to achieve this, it is preferable for the openings 2 to have such dimensions that an assembly 5 can be inserted through the application of pressure, and concretely, it is preferable for the openings 2 to be smaller than the assembly 5 as long as the assembly 5 can be inserted.

In addition, the portions for holding the solar battery elements 3 within the container 1 are not like the end portions of the solar battery elements 3 in the prior art, but the assemblies 5 are inserted into the openings 2 of the container 1 for holding the assemblies 5, and therefore, the surface portions of the assemblies 5 are held in such a manner that the area of contact between the container 1 and the assemblies 5 increase, and thus, stress applied to individual solar battery elements 3 due to impact or the like from the outside can be dispersed. Furthermore, cracking and chipping can be prevented from occurring in end portions of the solar battery elements 3 even through vibrations at the time of transportation or handling or through impact when being dropped because the assemblies 5 are held through the entirety of the surface.

As a result, the buffering material can be removed instead of simply reducing the ratio of the buffering material occupied in a receptacle, such as a container or a cardboard box, according to the prior art, and therefore, the number of solar battery elements contained in the receptacle to be shipped can be increased.

At this time, it is preferable for the number of solar battery elements packed with a heat-shrinkable film to be 10 to 50, and it is more preferable for it to be approximately 15 to 30. In the case where the number of layered solar battery elements is small, for example, 10, the width of the openings 2 becomes small, and it is necessary to increase the precision in processing, and therefore, the cost for processing to form the openings cannot be reduced and the cost for transportation becomes high. In addition, when the number of the solar battery elements is small, stress applied to one solar battery element becomes great even after the impact to the assembly 5 is dispersed, and when the thickness of the assembly is small, a sufficient strength cannot be gained, and therefore, there is a high possibility of cracking occurring in the solar battery elements when the assembly 5 is inserted into or taken out from an opening 2, or in a state where the assembly 5 is inserted and held.

In addition, electrodes for extracting the output to the outside and solder covering these electrodes are provided on the front surface and the rear surface of a solar battery element, and therefore, the solar battery element is slightly uneven in such a manner that this unevenness creates a gap between solar battery elements when the elements are layered. Therefore, in the case where the number of layered solar battery elements is great, for example, approximately 50, the total of the gaps in the assembly becomes great, making it difficult to align solar battery elements with end portions overlapping when a thermally shrinking process is carried out on the solar battery elements packed with a heat-shrinkable film, while in the case where the solar battery elements are packed in a state where end portions do not overlap, there is a high possibility of cracking occurring in the vicinity of the end portions and the electrodes of the solar battery elements.

In addition, according to one aspect, the above description discloses a solar battery element package, which is provided with solar battery element assemblies 5 in which a plurality of layered solar battery elements 3 are held to each other as described above and a container 1 having openings 2 where the above described solar battery element assemblies 5 are placed inside the openings 2, and where the solar battery elements are layered so that the electrode on the surface side which does not receive light on each solar battery element 3 faces the same direction, as well as a manufacturing method for the same.

When focusing on this configuration, a plurality of layered solar battery elements are held to each other so as to provide a solar battery element assembly 5, and thus, a sufficient strength can be secured in the solar battery element assembly 5 as a whole. Accordingly, there is an advantage in that chipping and cracking of solar battery elements can be prevented from occurring at the time of packing work or transportation, and packing becomes easy in comparison with the case where solar battery elements 3 are separately held one by one according to the prior art.

In particular, the solar battery elements 3 are layered so that the rear surface electrode 25 on the surface side which does not receive light faces the same direction, and therefore, the direction of warping of the solar battery elements 3 can be made uniform in a certain direction, and thus, stress applied from the outside can be received by the entirety of the assembly 5, and a sufficient strength can be secured in comparison with the case where the solar battery elements are layered with the direction of warping being inconsistent.

In addition, according to another aspect, the above description discloses a solar battery element package, which is provided with solar battery element assemblies 5 in which a plurality of layered solar battery elements 3 are held to each other and a container 1 having openings 2 where the above described solar battery element assemblies 5 are placed inside the openings 2, and where a layer side of the above described solar battery element assembly 5 is located on the bottom surface side of the above described opening 2, as well as a manufacturing method for the same.

When focusing on this configuration, in addition to the advantage of the solar battery element assembly 5 where a plurality of layered solar battery elements are secured to each other as described above, there is the following advantage. In the case where the solar battery elements 3 are stacked flat when packed, for example, a problem arises where the weight of the respective solar battery elements 3 is applied and concentrated on the solar battery elements in the lower portion. In contrast, in the above described package, a solar battery element assembly 5 is placed within an opening 2 so that one layer side of the solar battery element assembly 5 is located on the bottom surface side of the opening 2. Therefore, the weight of the respective solar battery elements 2 can be dispersed instead of being concentrated on a particular element at the time of packing. Accordingly, there is an advantage that chipping and cracking can be more effectively prevented from occurring in the solar battery elements at the time of packing work or transportation in comparison with the case where the respective solar battery elements 3 are packed in a state of being stacked flat according to the prior art.

In addition, in accordance with a method for packing solar battery elements 3 according to another embodiment of the present invention, it is preferable to provide notches 10 on the inner surfaces of the openings 2 provided in the container 1 (more specifically, inner walls forming openings 2) in the direction in which the solar battery elements are layered.

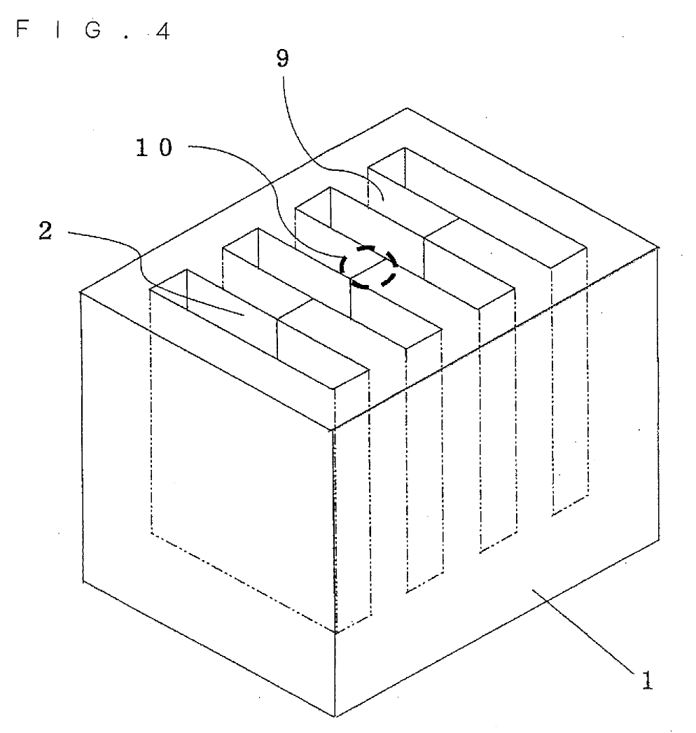

FIG. 4 is a schematic diagram illustrating a method for packing according to another embodiment of the present invention. 1 indicates a container, 2 indicates openings, 9 indicates partitions and 10 indicates a cut in a portion surrounded by a dotted line. Cuts 10 are formed in the direction in which the solar battery elements 3 are layered. More specifically, the cuts 10 are formed in the inner surfaces which face the front surfaces and the rear surfaces of the assemblies 5 from among the inner surfaces of the openings 2 in the direction in which the solar battery elements 3 are layered and in the direction of the depth of the openings 2. Furthermore, the present container 1 has a plurality of openings 2 formed so as to be aligned in the direction in which the assemblies 5 are layered. In addition, the above described cuts 10 are formed in partitions 9 for partitioning the respective openings 2. The cuts 10 are formed so as to connect adjacent openings 2.

Here, a plurality of openings 2 are provided as described above, and thus, a plurality of assemblies 5 can be efficiently packed. In addition, the plurality of openings 2 are formed so as to be aligned in the direction in which the assemblies 5 are layered, and therefore, portions which are relatively excellent in resistance to weight and resistance to impact (for example, portions corresponding to the layer sides of the assemblies 5) and portions which are relatively inferior (for example, portions corresponding to the front surfaces and the rear surfaces of the assemblies 5) can be specified in the package. As a result, it becomes easy to handle the package by paying attention to such properties.

As described above, when the solar battery element 3 undergoes the processing of the element, such as diffusion and sintering of electrodes, warping occurs in the substrate 21 through heat stress and the like, and in particular, when the thickness of the solar battery elements 3 is small, warping caused by the processing of element becomes great. When the solar battery elements 3 warp greatly, the solar battery elements 3 which make contact with the partitions 9 easily receive stress in the vicinity of the center where warping is great. In the case where cuts 10 are provided and a load is applied from the outside of the container 1, the stress on the assemblies 5 from the container 1 is relieved when the cuts 10 open. More specifically, when an assembly 5 is inserted into an opening 2, partitions 9 change their forms and move so that the cuts 10 open by the amount of warping. As a result, the stress on the assembly 5 from the container 1 is relieved. In the case where no cuts 10 are provided in this manner, the effects is great when the number of solar battery elements 3 forming assemblies 5 is great, and there is a high possibility of cracking occurring in the solar battery elements 3 at the time of the insertion and removal of an assembly 5 into and from an opening 2. However, when cuts 10 are provided in the inner surfaces of the openings 2 in the direction in which the solar battery elements 3 are layered, it becomes possible for the partitions 9 to move slightly in addition to the above described effects, and therefore, the partitions 9 move in the direction in which the solar battery elements warp so that stress applied to the vicinity of the center of the solar battery elements 3 can be relieved, making the insertion and removal of an assembly 5 into and from an opening 2 easy and safe, and thus, the working efficiency increases. In addition, in the case where the number of solar battery elements 3 used in assemblies 5 is great and the thickness of one solar battery element 3 is small, cracking can be particularly prevented from occurring in the solar battery elements 3. Furthermore, though cuts 10 can provide movement to partitions 9 even if they are not provided in the vicinity of the center of the partitions 9, it is preferable to provide the cuts 10 in the vicinity of the center on the inner surfaces of the openings 2 because warping is the greatest in the center portion of the solar battery elements 3.

In addition, the cuts 10 are formed so as to connect adjacent openings 2, and therefore, the partitions can move and change their forms greatly through their flexibility, and thus, stress applied to the solar battery elements 3 can be more effectively relieved.

Furthermore, in accordance with the method for packing solar battery elements 3 according to the present invention, it is preferable to provide recesses 11 in the inner surfaces of the openings 2 provided in the container 1 (more specifically, inner walls forming the openings 2) in the direction in which the solar battery elements 3 are layered.

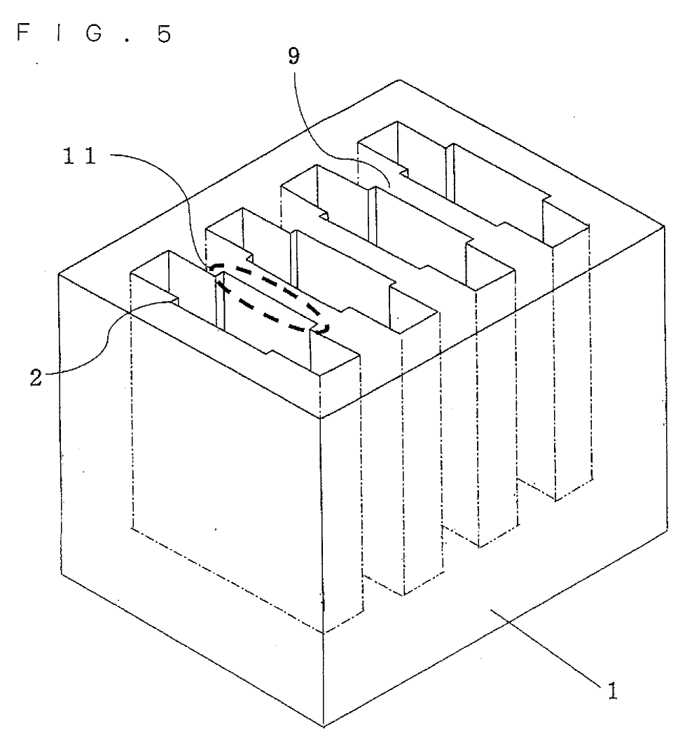

FIG. 5 is a schematic diagram showing the packing method according to another embodiment of the present invention. 1 indicates a container, 2 indicates openings, 9 indicates partitions and 11 in a portion surrounded by a dotted line indicates a recess. This recess 11 is formed in the direction in which solar battery elements 3 are layered. More specifically, recesses 11 are formed in pairs of inner surfaces which face the front surfaces and the rear surfaces of the assemblies 5 from among the inner surfaces of the openings 2 so as to extend in the direction of the depth of the openings 2. Here, though recesses 11 are formed in the pairs of inner surfaces which face the front surfaces and the rear surfaces of the assemblies 5 from among the inner surfaces of the openings 2, recesses may be formed only on either side. Recesses 11 may of course be formed at the bottoms of the container 1.

By providing such a structure, in addition to the above described effects, when an assembly 5 is inserted into an opening 2, the pressure through the contact between the vicinity of the center of the solar battery elements 3 and the partitions 9 becomes weak, and stress applied to the vicinity of the center of the solar battery elements 3 is relieved even in the case where the solar battery elements 3 warp greatly. As a result, the insertion and removal of assemblies 5 into and from the openings 2 become easy and safe, improving workability.

In addition, in accordance with the method for packing solar battery elements 3 according to the present invention, the container 1 has a plurality of openings in the direction in which the solar battery elements 3 are layered, and it is preferable for penetrating portions 12, which connect adjacent inner surfaces, to be provided in the inner surfaces of the plurality of openings 2 (more specifically, inner walls forming the openings 2).

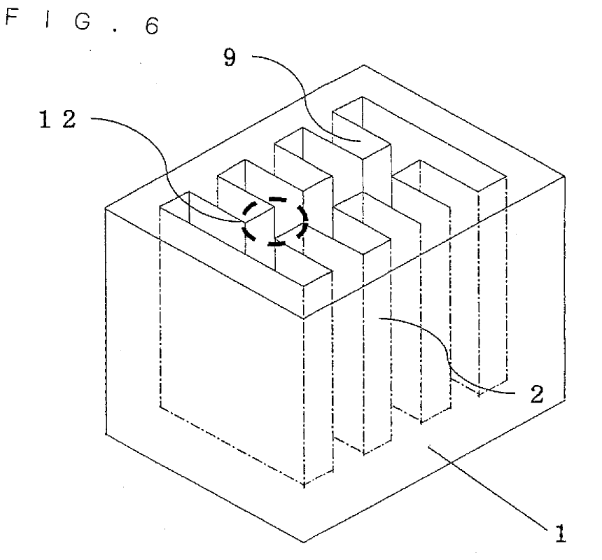

FIG. 6 is a schematic diagram showing the packing method according to another embodiment of the present invention. 1 indicates a container, 2 indicates openings, 9 indicates partitions and 12 in a portion surrounded by a dotted line indicates a penetrating portion. The penetrating portion 12 is formed in the partition 9 for partitioning the openings 2. Penetrating portions 12 are formed at the recess which extends from the opening to the bottom of the opening 2 in each partition 9 so as to connect the spaces within the respective openings 2. These penetrating portions 12 are one type of the above described recesses 11, that is to say, they can be said to be a version of the above described recesses 11 in such a form as to connect adjacent openings 2.

Furthermore, by providing such a structure, in addition to the above described effects, particularly in the case where the width of the penetrating portions 12 is 70% or less of the width of the solar battery elements 3, the assemblies 5 are firmly secured to the inside of the openings 2 and stress applied to the end portions of the solar battery elements 3 can be relieved, and therefore, the possibility of cracking occurring to the end portions of the solar battery elements 3 during transportation can be reduced. In addition, it is better for the end portions of the penetrating portions 12 in the partitions 9 to be provided with rounded portions, such as R surfaces and C surfaces, and thus, the load of the solar battery elements 3 which is applied at the time of insertion and the removal of the assemblies 5 can be reduced.

In addition, the penetrating portions 12 are formed so as to connect adjacent openings 2, and therefore, stress applied to the solar battery elements 3 can be relieved in adjacent openings 2 in a relatively simple configuration.

In addition, in accordance with the method for packing solar battery elements 3 according to the present invention, it is preferable to provide trenches (recesses in trench form) 13 in the bottom corners of the openings 2.

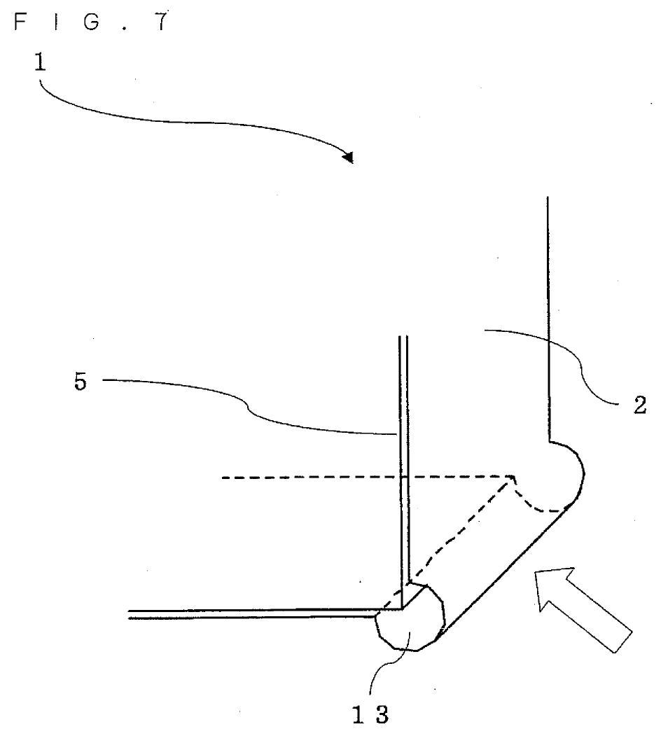

FIG. 7 is a diagram showing an enlarged bottom corner A in an opening of FIG. 3 in accordance with the packing method according to another embodiment of the present invention. 2 indicates openings, 5 indicates assemblies and 13 indicates trenches. Trenches 13 are provided in the bottom corners (corner regions) of the openings 2. More specifically, trenches 13 are formed in portions which face end portions where the respective layer sides of the assemblies 5 cross, here in the bottom corners where the bottom surfaces and the side surfaces (side surfaces facing the layer side surfaces of the assemblies 5) from among the inner surfaces of the openings 2 cross.

By providing a structure as shown in FIG. 7, the trenches 13 absorb the impact to the corner portions of the assemblies 5, which are relatively weak against impact and easy to chip, in the case where there are vibrations at the time of transportation or handling and impact when being dropped, and therefore, impact to the corner portions of the assemblies 5 can be relieved, and such a problem as chipping in a corner portion of the solar battery elements 3 can be prevented. In addition, the form of the trenches 13 is not particularly limited and may be in arc form as shown in FIG. 7, or may be in V form when viewed in the direction along the above described bottom corners. Furthermore, a trench may be provided so as to surround the bottom corners. In addition, various forms of trenches which keep the bottom corners in the corner portions of the openings 2 and the corner portions of the assemblies 5 from making contact with each other can be provided.

In addition, in accordance with the method for packing solar battery elements 3 according to the present invention, it is preferable to provide a lid (lid body) 6 for closing the openings 2 so that the lid 6 is fit to the container 1.

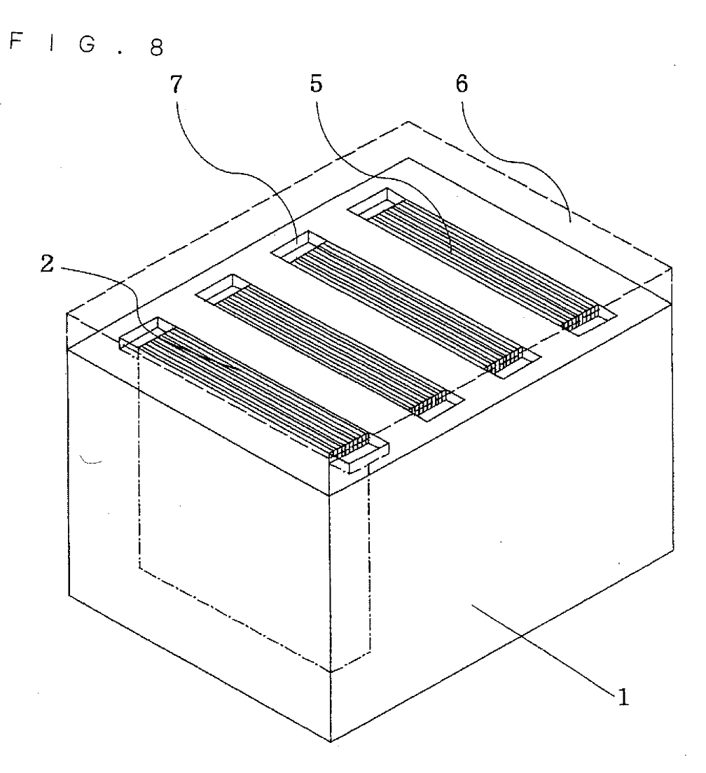

FIG. 8 is a schematic diagram showing the packing method according to another embodiment of the present invention. 1 indicates a container, 2 indicates openings and 6 indicates a lid. The lid 6 has dimensions which are sufficiently great to cover at least part of the openings 2 in a plan view. Here, the lid 6 is formed so as to cover all the openings 2, more specifically, in plate form corresponding to the form and the size of the container 1 in a plan view. In addition, the lid 6 is attached to the top of the container 1 so as to close the openings 2.

In addition, the present embodiment provides an engagement structure where the lid 6 and the container 1 fit each other. More specifically, recesses 7 for engagement are provided in the top surface of the container and on the two sides of the openings 2, while the lid 6 is provided with protrusions for engagement which can be engaged with these recesses 7 for engagement. Thus, the lid 6 is attached to the container 1 so that the protrusions for engagement are engaged with the recesses 7 for engagement. As a result, it becomes difficult for the lid 6 to be shifted or to come off from the container 1 in a packed state, and the strength of the packing can be easily increased.

By providing a structure as shown in FIG. 8, the assemblies 5 can be prevented from coming off from the openings 2 and the upper portion of the assemblies 5 can be protected, and therefore, impact from all the surfaces can be prevented, and the assemblies 5 held in the container 1 can be contained in the receptacle more safely so as to be transported to the shipping destination. The lid 6 may be formed of the same material as that of the container 1 and may be secured with a fixture (not shown), such as rubber or tape. In addition, the lid 6 may be inserted into and secured to the container 1 so as to be slidable.

In addition, in accordance with the method for packing solar battery elements 3 according to the present invention, it is preferable for the lid 6 to be made of the same container as the container 1.

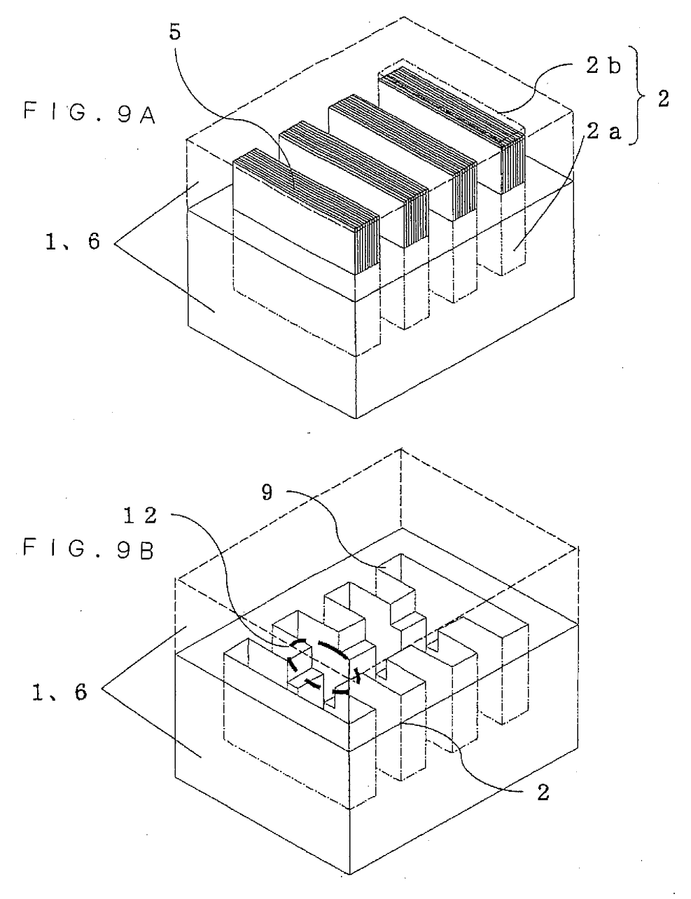

FIG. 9 is a schematic diagram illustrating the packing method according to another embodiment of the present invention. FIG. 9(a) shows a state where two containers are stacked and secured. FIG. 9(b) shows a state where two containers having penetrating portions are stacked and secured. 1 indicates containers, 2 indicates openings, 5 indicates assemblies, 6 indicates lids and 12 in a portion surrounded by a dotted line indicates a penetrating portion. FIG. 9(a) shows a state where the lower halves of the assemblies 5 are contained in the openings 2a of the container 1 on one side and the upper halves of the assemblies 5 are contained in the openings 2b of the lid 6 on the other side. In addition, the penetrating portion 12 shown in FIG. 9(b) has a recess in step form, in other words, is formed as a recess in approximately T shape. Furthermore, openings 2 are connected via penetrating portions in approximately cross form in a state where the lid 6 is attached to the container 1.

By providing the structure shown in FIG. 9(a), the form and the size of the container 1 and the lid 6 can be made the same, making it unnecessary to prepare a container 1 and a lid 6 separately, and thus, the container 1 becomes the lid 6 and it is not necessary to provide the lid 6 separately, and the cost for transportation can be reduced.

Furthermore, by providing the structure shown in FIG. 9(b), in addition to the above described effects, gaps may be created in the center portions of the assemblies 5, and the assemblies can be packed and secured, taking the warping of the solar battery elements into consideration. In addition, the penetrating portions 12 are in step form as shown in FIG. 9(b), and thus, the cross portions in approximately cross form become the most flexible in a state where the lid 6 is attached to the container 1. Accordingly, the assemblies 5 can be held in a more appropriate manner without the application of stress to the center portion of the solar battery elements 3, which are the portions where the warping in the assemblies 5 has the greatest effect.

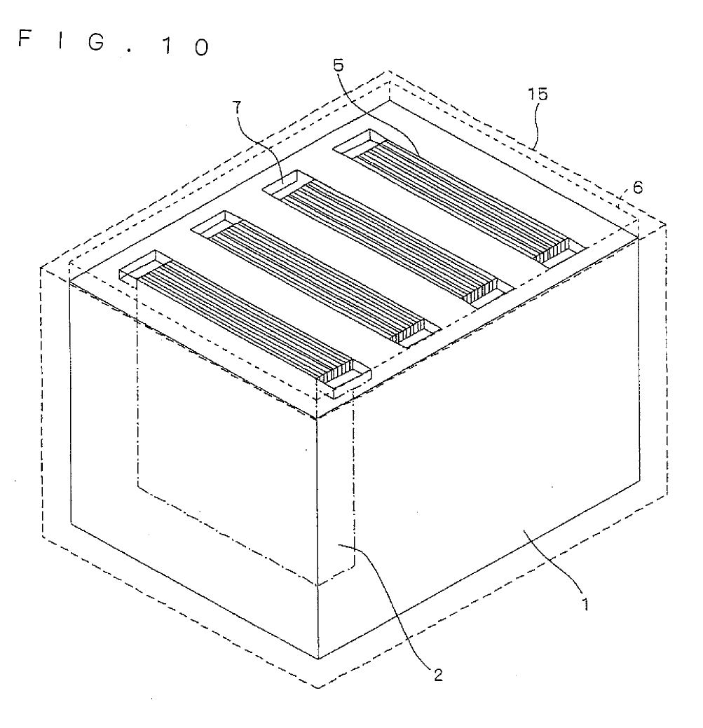

Furthermore, FIG. 10 is a schematic diagram illustrating the packing method according to another embodiment of the present invention. 1 indicates a container, 2 indicates openings, 5 indicates assemblies and 15 indicates a heat-shrinkable film for packing a container.

It is preferable for the method for packing solar battery elements 3 according to the present invention to include a third packing step of fitting the lid 6 to the container 1, which is then covered with a heat-shrinkable film 15, and a second heating step of heating the heat-shrinkable film 15 so that the lid 6 and the container 1 are integrated.

By providing this structure, the container 1 is bound so that the assemblies 5 are firmly secured within the openings 2 as a result of the third packing step of covering the container with a heat-shrinkable film 15 together with the assemblies 5, which do not come off from the openings 2, and the second heating step of carrying out a thermally shrinking process on the heat-shrinkable film 15. In addition, the electrodes 24 and 25 can be effectively prevented from being oxidized by the air when sealed airtight with the heat-shrinkable film 15. Here, the lid 6 may be omitted so that the container 1 is covered with a heat-shrinkable film 15 in a state where the assemblies 5 are contained in the openings 2, and the heat-shrinkable film 15 is heated, and thus the assemblies 5 are held within the openings 2 of the container 1.

In addition, films, such as of polyvinyl chloride, polystyrene, polyester, polyethylene and polyolefin, can be used in the same manner as the heat-shrinkable film 15 for packing the container 1 or the container 1 and the lid 6, and a general shrink packing apparatus can be used. In the third packing step, the container 1 is packed with a heat-shrinkable film 15 in accordance with a method, such as an L type sealing method or an I type sealing method. Then, in the second heating step, a thermal shrinking process is carried out on the heat-shrinkable film 4 in a heating apparatus, which is referred to as a shrink tunnel, at a temperature of approximately 90° C. to 140° C., and thus, the heat-shrinkable film 4 adheres to the outside of the container 1.

As a result, in addition to the above described effects, chipping and cracking can be prevented from occurring in the solar battery elements 3 through vibrations at the time of transportation or handling, or through the impact when being dropped, and thus, the assemblies 5 held in the container 1 can be contained safely in the receptacle and transported to the shipping destination.

Here, the embodiments of the present invention are not limited only to the above described examples, but various modifications are of course possible as long as the gist of the present invention is not deviated from.

The heat-shrinkable film 4 used for the formation of the assemblies 5 and the heat-shrinkable film 15 used to cover the outside of the container 1, for example, may be the same film or may be different films which may be separately prepared for different shrink packing.

Cuts 10 formed in the partitions 9 for partitioning the openings 2 may not have such a depth as to reach the end portion of the assemblies 5 as long as the cuts 10 can allow the partitions 9 to move slightly.

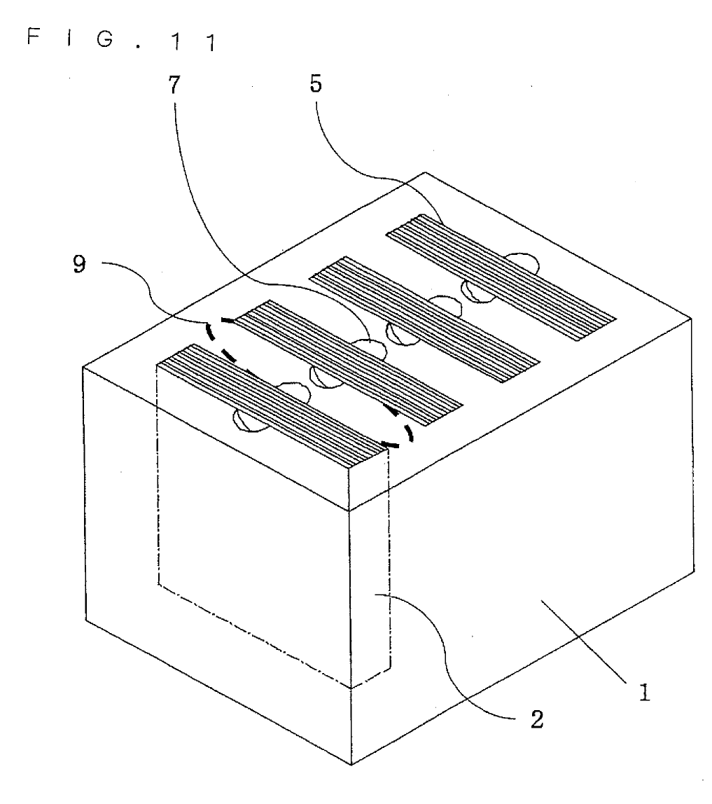

In addition, FIG. 11 shows another container 11 according to the present invention. 1 indicates a container, 2 indicates openings, 5 indicates assemblies, 7 indicates notches and 9 indicates partitions. The notches 7 are formed in approximately center portions at the ends of the partitions 9 on the opening 2 sides and have a form as that of a recess, which is one-quarter of a sphere. In addition, the assemblies 1 are partially exposed to the outside from the notches 7 in a state where the assemblies 5 are contained within the openings 2. In this structure, an assembly 5 can be held through notches 7 so that the assembly 5 can be easily inserted into or removed from an opening, and therefore, the workability increases, which is preferable.

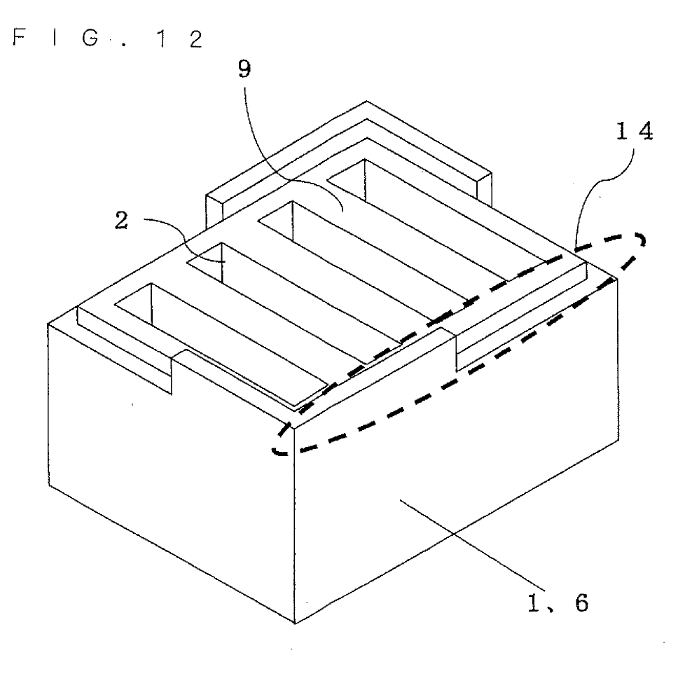

In addition, FIG. 12 is a diagram showing another container 1 according to the present invention where fitting portions 14 are provided in a joining portion with a lid 6.

1 indicates a container, 2 indicates openings, 9 indicates partitions and 14 in the portion surrounded by a dotted line is an fitting portion. The fitting portion 14 is formed on the four sides around the periphery of the container 1. Each fitting portion 14 has a protruding portion which extends from the center portion of each side to one end portion on the side in the longitudinal direction and a recess portion which extends from this center portion to the other end portion on the side. In addition, one pair of containers 1 is combined in such a manner that each protruding portion is engaged with the corresponding recess portion. In this structure, the container 1 and the lid 6 can be secured more firmly, and therefore, such problems that the assemblies 5 become loose within the container 1 or the assemblies 5 come off from the openings can be solved, which is preferable. In addition, an impact on a side of the container 1 can be relieved by the fitting portions 14, and therefore, the assemblies 5 can be held in a more appropriate manner. Therefore, the fitting portions 14 can be provided as protruding and recess portions in the outer peripheries of the container 1 and the lid 6, and when recesses and protrusions in L shape are provided in the corner portions along the outer peripheries as shown in FIG. 12, the container 1 and the lid 6 have the same form, and thus, it becomes unnecessary to separately fabricate the lid 6.

Furthermore, in the case where a plurality of openings 2 are formed in the container 1, it is not necessary to insert assemblies 5 into all of these openings 2, but in the case where the number of openings 2 is greater than the number of assemblies 5, dummy assemblies made of, for example, a buffering material may be inserted into the extra openings 2.

In addition, a perforation may be provided to the heat-shrinkable film. When a perforation is provided, it becomes easy to remove the solar battery elements 3, and therefore, the solar battery elements 3 can be prevented from cracking, particularly when the solar battery elements are removed from the element package.

In addition, in a solar battery element in accordance with the method for packing solar battery elements according to the present invention, it is preferable for the front surface electrode 24 and/or the rear surface electrode 25 of which the main component is silver not to be covered with solder. In shrink packing according to which a thermal shrinking process is carried out on a heat-shrinkable film 4 with which an element assembly, where a plurality of solar battery elements 3 are layered, is covered, the solar batteries are bound to each other, and therefore, a load is inevitably applied to the front surface electrode 24 and the rear surface electrode 25, which protrude to the outside from the semiconductor substrate 21. Therefore, the load applied to the electrode portions becomes greater when the electrodes are coated with solder, unnecessarily increasing the thickness of the electrodes, and thus, micro-cracking occurs in the vicinity of the electrodes which may cause cracking. In particular, it is difficult to coat the electrodes with solder having a uniform and optimal thickness in accordance with a method for coating, such as a dipping method or wave soldering method, and therefore, there is a risk that a load may be concentrated on a portion having a great thickness, and cracking may occur in this portion. Accordingly, when the electrodes of the solar battery elements are not coated with solder, stress can be prevented from concentrating on an electrode and its periphery due to the coating with solder and the effects of preventing cracking of the solar battery elements are great, and a greater number of solar battery elements can be layered and packed with a heat-shrinkable film 4 even in the case where a great number of solar battery elements of which the substrates are thin are layered and packed with a shrunk film with a great binding force of the heat-shrinkable film, and thus, costs for transportation can be reduced.

In addition, it is preferable for the front surface electrode 24 and/or the rear surface electrode 25 shown in FIG. 15 to be used for a solar battery element formed of three or more busbar electrodes. When solar battery elements 3 undergo an element process, such as diffusion and electrode sintering, the substrate warps as a result of thermal stress, and in particular, when the solar battery element 3 is thin, warping caused by the element process becomes great. In addition, the solar batteries are bound to each other through shrink packing, and therefore, a force is applied in such a direction as to make warping greater in such a manner that great stress is applied particularly to the vicinity of the center of the semiconductor substrate. However, in a solar battery element where three or more busbar electrodes are formed as compared with the conventional solar battery element having two busbar electrodes, resistance loss of the electrodes can be reduced even when the width of the busbar electrodes becomes small, and therefore, the effects of thermal stress applied at the time of sintering can be relieved by making the width of the busbar electrodes smaller, and thus, the warping of the substrate is mitigated. In addition, the busbar electrodes are formed in the vicinity of the center to which stress is greatly applied when the substrate warps, and therefore, cracking of the substrate can be prevented when the busbar electrodes work as a reinforcing material. Accordingly, stress applied to the vicinity of the center when a plurality of layered solar battery elements are packed with a shrunk film can be relieved so that cracking can be effectively prevented from occurring, and therefore, a greater number of solar battery elements can be layered and packed with a heat-shrinkable film 4, and thus, the cost for transportation can be reduced.

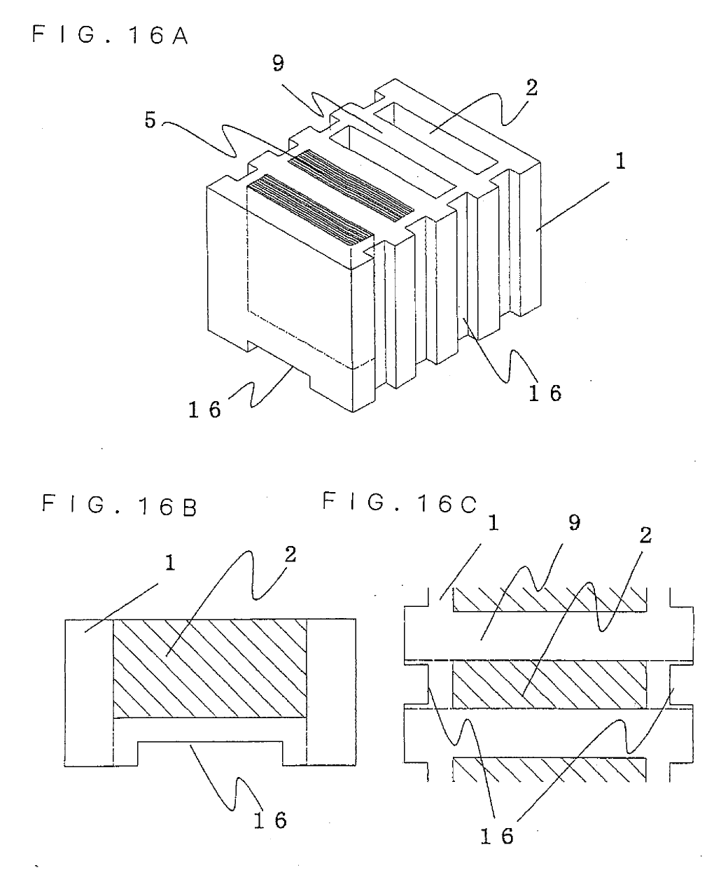

FIG. 16 is a schematic diagram showing a packing method and a package according to another embodiment of the present invention. This package is provided with a container 1, openings 2 and partitions 9. The difference with the package shown in FIG. 3 is described as follows. The outer surface of the container 1 has projection and concave. More specifically, the side portions corresponding to the layer sides of the assemblies 5 from among the outer surfaces of the container 1, that is to say, the side portions corresponding to the locations of the openings 2 are formed so as to have recesses 16, and the other portions are formed so as to have protrusions. In other words, as shown in FIGS. 16(b) and 16(c), the locations where recesses 16 are provided are within ranges where the openings 2 are projected in the horizontal or perpendicular directions.

By providing the structure where recesses 16 are provided around the container 1 as shown in FIG. 16, it becomes difficult for impact to be directly applied to the recesses of the container 1, and instead, the impact is easily applied mainly to the protrusions on the outside of the container 1 in the case where there are vibrations at the time of transportation or handling, or impact when being dropped. Therefore, this impact can be prevented from being directly conveyed to the solar battery elements 3. Here, the width of the recesses 16 can of course be appropriately set within the above described range of the projection of light, and the depth of the recesses 16 can of course be adjusted in order to secure a sufficient strength in the portions of the protrusions.

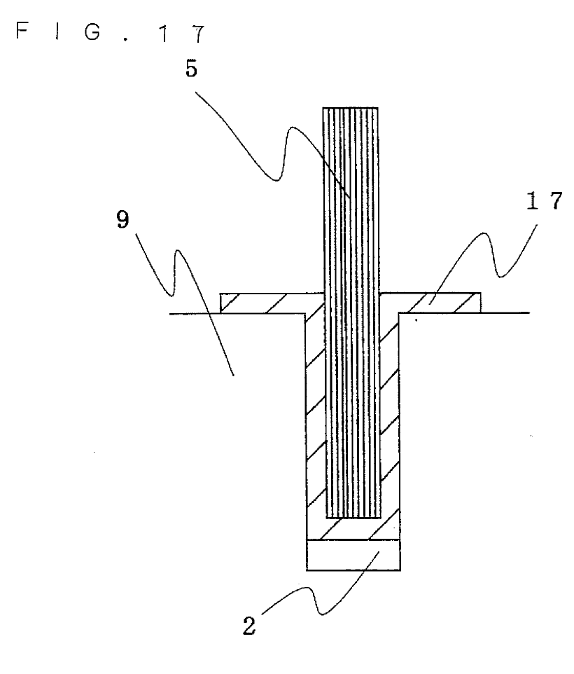

In addition, as shown in FIG. 17, the layer sides and the front and rear surfaces of an assembly 5 may be sandwiched in a buffering sheet 17 in approximately U shape before the assembly 5 is inserted into an opening 2 together with the buffering sheet 17. At this time, the buffering sheet 17 is compressed and intervenes between the front and rear surfaces of the assembly 5 and the inner surfaces of the opening 2 so that the assembly 5 is held in a floating state by the pressing and holding force of the sheet in such a manner that the bottom of the assembly 5 does not make direct contact with the bottom of the opening 2. As a result, even in the case where a great impact is applied to the bottom of the container 1 through the vibration at the time of handling or impact when being dropped, this impact can be prevented from being directly conveyed to the bottom of the solar battery elements 3.

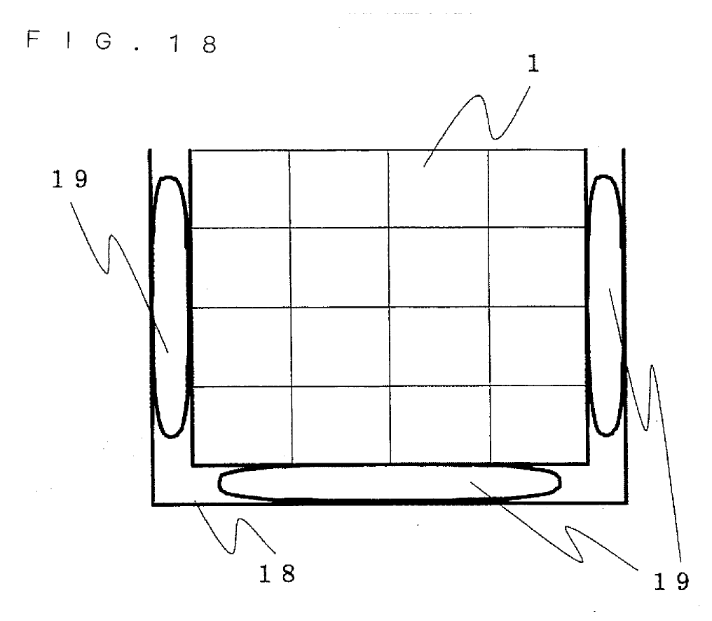

Furthermore, it is preferable for a plurality of packages where solar battery elements 3 are packed into a container 1 to be contained in a container for transportation, such as a cardboard box, and transported simultaneously. At this time, a container for transportation 18, which can contain a plurality of packages having containers 1 as described above, is prepared as shown in, for example, FIG. 18, and it is preferable to contain the containers 1 in such a state that a hollow elastic material 19 (air cushion or the like) is installed in at least one portion from among a bottom portion and side portions on the inner surfaces of this container for transportation 18. In this manner, a hollow elastic material 19 is provided so that the hollow elastic material 19 changes its form so as to absorb the impact on the container for transportation 18, and the impact on the container 18 can be mitigated when there are vibrations at the time handling or impact when being dropped, and furthermore, according to the present invention, chipping and cracking can be prevented from occurring in the solar battery elements 3. At this time, it is more preferable for the hollow elastic material to be placed with a space so that the hollow elastic material can change its form in the container for transportation 18. A space as described above may be provided in the space between the bottom edges and side edges of the container for transportation 18.

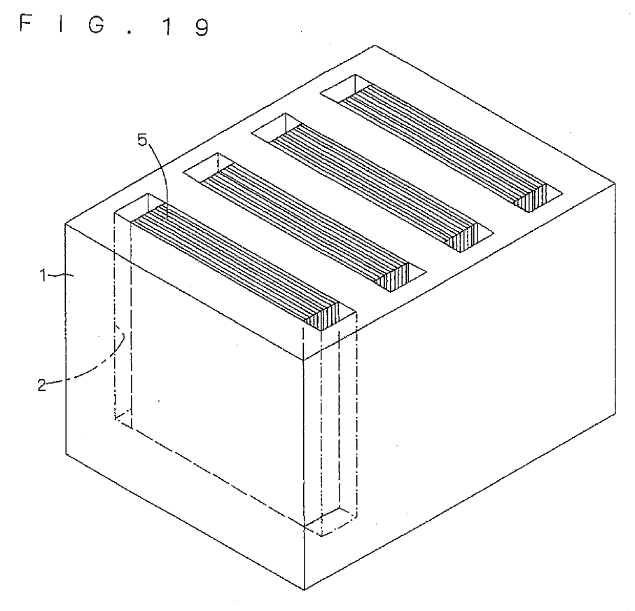

In addition, the configuration having recesses in the inner walls forming openings 2 is not limited to the example shown in FIG. 5 where recesses are formed in the inner surfaces facing the front and rear surfaces of the assemblies 5. For example, as shown in FIG. 19, recesses may be formed in the inner surfaces facing the side surfaces of the assemblies 5. In the example shown in FIG. 19, the width of the openings 2 is made greater than the width of the assemblies 5, and thus, recesses are formed. As a result, the assemblies 5 can be prevented from directly receiving impact in the lateral direction applied to a side surface of the container 1. That is to say, in the above described configuration, the sides of the assemblies 5 of the solar battery elements and the inner surfaces of the openings 2 can be prevented from making direct contact. As a result, even in the case where impact is applied to a side of the container 1 at the time of the handling of the container 1 when being dropped, this impact can be prevented from being conveyed directly to a side of the solar battery elements 3.

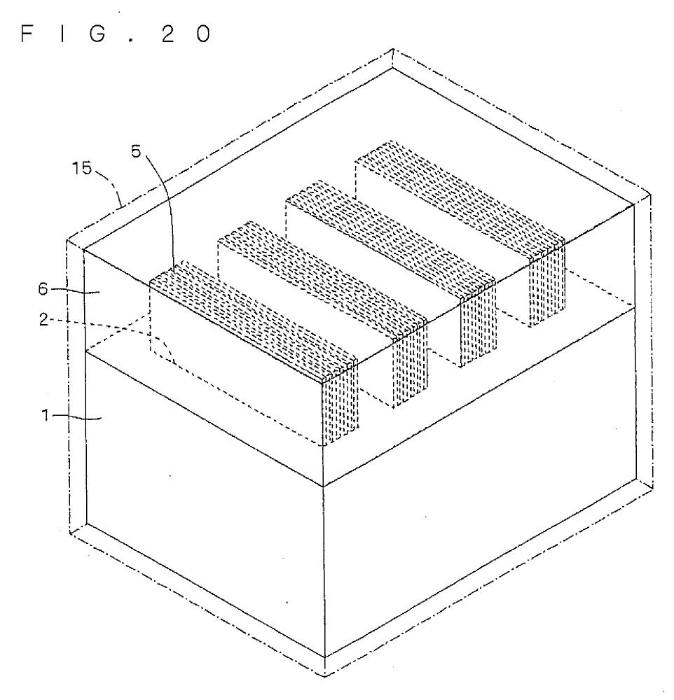

In addition, as shown in FIG. 20, the size of the container 1 may be reduced and the size of the lid may be increased in the example shown in FIG. 10, and furthermore, the container 1 and the lid 6 may of course be formed so as to have the same size.

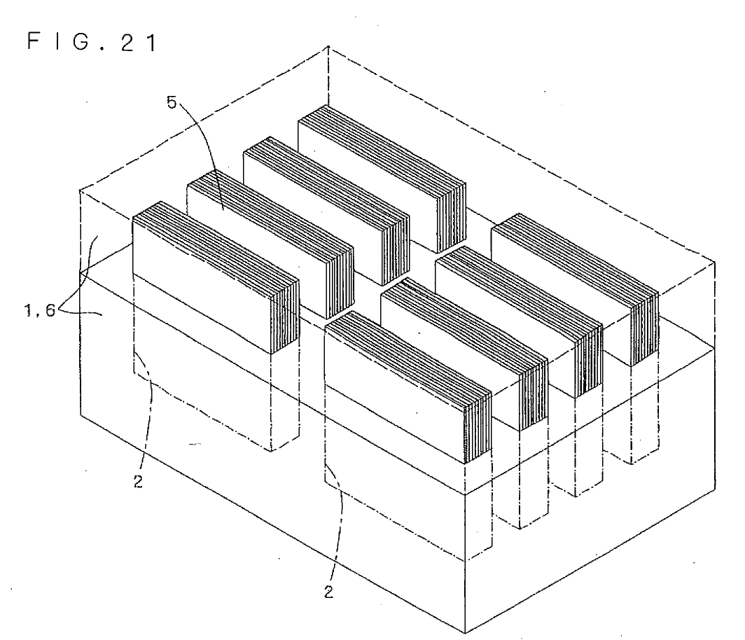

Moreover, as shown in FIG. 21, a plurality of rows (here, 2) of openings 2 may be provided in the direction of the width.

Though this invention is described in detail, the above descriptions are illustrative in all aspects, and this invention is not limited to these. It can be understood that an infinite number of modifications which are not illustrative can be assumed without deviating from the scope of this invention.

1. A method for packing solar battery elements, comprising:
a first packing step of covering a plurality of layered solar battery elements with a heat-shrinkable film;
a first heating step of heating the heat-shrinkable film to hold the solar battery elements as an assembly; and
a second packing step of inserting the assembly into an opening of a container containing the opening for holding the assembly.

2. The method for packing solar battery elements according to claim 1, wherein a cut is provided in the inner surface of the opening in the direction of the layering of the solar battery elements.

3. The method for packing solar battery elements according to claim 1, wherein a recess is provided in the inner surface of the opening in the direction of the layering of the solar battery elements.

4. The method for packing solar battery elements according to claim 1, wherein the container has a plurality of openings in the direction of the layering of the solar battery elements and is provided with a penetrating portion for connecting adjacent inner surfaces of the plurality of openings.

5. The method for packing solar battery elements according to claim 1, wherein a trench is provided in the bottom corner of the opening.

6. The method for packing solar battery elements according to claim 1, wherein a lid for covering the opening is provided, and the lid is fit to the container.

7. The method for packing solar battery elements according to claim 6, wherein the lid is made of the same container as the container.

8. The method for packing solar battery elements according to claim 6, further comprising:
a third packing step of fitting the lid to the container and covering the two with a heat-shrinkable film; and
a second heating step of heating the heat-shrinkable film to integrate the lid and the container.

9. A package for solar battery elements, comprising:
an assembly of solar battery elements in which a plurality of layered solar battery elements are hold to each other; and
a container containing an opening, where the assembly of solar battery elements is placed inside the opening, wherein
each of the solar battery elements has an electrode at least on its nonlight-receiving surface, and the assembly of solar battery elements has layers where the electrodes face the same direction.

10. A package for solar battery elements, comprising:
an assembly of solar battery elements in which a plurality of layered solar battery elements are held to each other; and
a container containing an opening, where the assembly of solar battery elements is placed inside the opening, wherein
a side of the layers of the assembly of solar battery elements is located on the bottom surface side of the opening.

11. The package for solar battery elements according to claim 9, wherein the assembly of solar battery elements is held in an airtight state with a heat-shrinkable film which covers the assembly.

12. The package for solar battery elements according to claim 9, wherein the container includes a cut in an inner wall which forms the opening.

13. The package for solar battery elements according to claim 9, wherein the container includes a recess in an inner wall which forms the opening.

14. The package for solar battery elements according to claim 9, wherein the opening is approximately in rectangular parallelepiped form and includes a trench in its bottom corner.

15. The package for solar battery elements according to claim 9, wherein the container includes a plurality of openings.

16. The package for solar battery elements according to claim 15, wherein the plurality of openings are provided to be aligned in the direction in which the solar battery elements which form assemblies of solar battery elements placed inside the openings, which are the same as the assembly, are layered.

17. The package for solar battery elements according to claim 16, wherein the container includes a cut in the inner wall which forms the openings, wherein
the cut is provided to connect adjacent openings.

18. The package for solar battery elements according to claim 16, wherein the container includes a recess in the inner wall which forms the openings, wherein
the recess is provided so as to connect adjacent openings.

19. The package for solar battery elements according to claim 9, wherein an outer surface of the container has projection and concave.

20. The package for solar battery elements according to claim 19, wherein the concave of the outer surface of the container corresponds to the location of the opening.

21. The package for solar battery elements according to claim 9, further comprising a lid for covering at least a portion of the opening in a state where the assembly of solar battery elements is placed inside the opening.

22. The package for solar battery elements according to claim 21, wherein the lid is fit to the container.

23. The package for solar battery elements according to claim 21, wherein the lid has the same form as the container.

24. A package for solar battery elements, wherein the package for solar battery elements according to claim 9 is sealed airtight with a heat-shrinkable film.

25. A method for packing solar battery elements, comprising:
a step of layering solar battery elements including an electrode at least on nonlight-receiving surface in such a manner that the electrodes face the same direction;
an assembly forming step of forming an assembly of solar battery elements by holding a plurality of layered solar battery elements with a packing member; and
an assembly inserting step of placing the assembly of solar battery elements inside an opening of a container including the opening.

26. A method for packing solar battery elements, comprising:
an assembly forming step of forming an assembly of solar battery elements by holding a plurality of layered solar battery elements with a packing member; and
an assembly inserting step of inserting the assembly of solar battery elements into an opening of a container including the opening, to locate a side of the layers on the bottom surface side of the opening.

27. The method for packing solar battery elements according to claim 25, wherein the assembly forming step comprises forming an assembly of solar battery elements by covering the outside of a plurality of layered solar battery elements with a heat-shrinkable film and heating the heat-shrinkable film.
